(19) United States
(12) Patent Application Publication
(10) Pub. No.: US 2025/0265497 A1
(43) Pub. Date: Aug. 21, 2025

(54) SEMICONDUCTOR DEVICE AND TRAINING METHOD OF THE SAME

(71) Applicant: SAMSUNG ELECTRONICS CO., LTD., Suwon-si (KR)

(72) Inventors: Dongha KIM, Suwon-si (KR); Changyoung BAE, Suwon-si (KR); Ji Hun OH, Suwon-si (KR); Kwanyeob CHAE, Suwon-si (KR)

(73) Assignee: SAMSUNG ELECTRONICS CO., LTD., Suwon-si (KR)

(21) Appl. No.: 18/986,052

(22) Filed: Dec. 18, 2024

(30) Foreign Application Priority Data
Feb. 21, 2024 (KR) 10-2024-0025313
May 14, 2024 (KR) 10-2024-0063009

(51) Int. Cl. G06N 20/00; H01L 23/48

(52) U.S. Cl. CPC G06N 20/00; H01L 23/481

(57) ABSTRACT

A semiconductor device includes one or more core dies, through silicon vias that penetrate the one or more core dies, and a processor connected to the one or more core dies through a through silicon via of the through silicon vias. The processor generates a first command set including plural commands and plural clock signals having different phases for a target core die among the one or more core dies, and performs a training operation for the target core die based on the first command set and the plural clock signals.

### CROSS-REFERENCE TO RELATED APPLICATIONS

This application claims priority to Korean Patent Application No. 10-2024-0025313 filed in the Korean Intellectual Property Office on Feb. 21, 2024, and to Korean Patent Application No. 10-2024-0063009 filed in the Korean Intellectual Property Office on May 14, 2024, the entire contents of which being incorporated by reference herein.

### BACKGROUND

The present disclosure relates to a semiconductor device and a training method of a semiconductor device.

As the amount of a data that electronic devices must process increases, a high-capacity and a high-bandwidth memory devices are required. Particularly, in order to process the data at high speed, the use of memory devices that provide wide input/output in a multi-channel interface such as a high bandwidth memory (HBM) is increasing. Meanwhile, as the memory devices become higher capacity and higher performance, the operating frequency of the memory devices is rapidly increasing. As the operation speed of the memory devices increases, it becomes increasingly difficult to correct the reliability (a data integrity) of the data in the memory devices.

### SUMMARY

It is an aspect to provide a semiconductor device that transmits a data through through-electrodes (through-silicon vias, TSV) and a training method for the semiconductor devices.

According to an aspect of one or more embodiments, there is provided a semiconductor device comprising at least one core die; a plurality of through silicon vias (TSV) configured to penetrate the at least one core die; and a processor connected to the at least one core die through a TSV of the plurality of TSVs. The processor is configured to generate a first command set including a plurality of commands and a plurality of clock signals having different phases for a target core die among the at least one core die, and to perform a training operation for the target core die based on the first command set and the plurality of clock signals.

According to another aspect of one or more embodiments, there is provided a training method of a semiconductor device, the training method comprising writing a training pattern to a target core die of at least one core die by a processor connected to at least one core die through a plurality of through silicon vias; performing a training operation for a target core die based on a first command set including a plurality of commands for the target core die and a mode signal for a plurality of clock signals having different phases; and determining a reception timing of read data received from the target core die and a transmission timing of transmit data transmitted to the target core die based on a result of the training operation.

According to yet another aspect of one or more embodiments, there is provided a semiconductor device comprising at least one core die; and a processor connected to the at least one core die through a plurality of through silicon vias (TSV) that penetrate the at least one core die. The processor includes a training circuit configured to, when the processor operates in a training mode, perform a training operation for a target core die among the at least one core die by generating a mode signal for a first command set including a plurality of commands for the target core die and for a plurality of clock signals having different phases, and a physical layer configured to generate the first command set and the plurality of clock signals based on the mode signal.

### BRIEF DESCRIPTION OF THE DRAWINGS

FIG. 1 is a view showing a semiconductor device according to an embodiment.

FIG. 2 is a view showing a physical layer (PHY) according to an embodiment.

FIG. 3 is a view showing a command control slice according to an embodiment.

FIG. 4 is a view showing a data control slice according to an embodiment.

FIG. 5 is a view showing a configuration of a core die according to an embodiment.

FIG. 6 is a view showing a method in which a semiconductor device operates in a training mode according to an embodiment.

FIG. 7 is a view that specifically shows a reading training operation in the method of FIG. 6, according to an embodiment.

FIG. 8 is an exemplary timing diagram of signals between a processor and a memory device when performing a read training operation, according to some embodiments.

FIG. 9 is a view that specifically shows a writing training operation in the method of FIG. 6, according to an embodiment.

FIG. 10 is an exemplary timing diagram of signals between a processor and a memory device when performing a write training operation, according to some embodiments.

FIG. 11 is a view that specifically shows a command bus training operation in the method of FIG. 6, according to an embodiment.

FIG. 12 is an exemplary timing diagram of signals between a processor and a memory device when performing a command bus training operation, according to an embodiment.

FIG. 13 is a view showing a semiconductor package according to an embodiment.

FIG. 14 is a perspective view showing an example of a semiconductor package according to an embodiment.

### DETAILED DESCRIPTION

In the following detailed description, only certain embodiments of the present disclosure have been shown and described, simply by way of illustration. As those skilled in the art will realize, the described embodiments may be modified in various different ways, all without departing from the spirit or scope of the present disclosure and the appended claims.

Accordingly, the drawings and description are to be regarded as illustrative in nature and not restrictive. Like reference numerals designate like elements throughout the specification. In the flowcharts described with reference to the drawings in this specification, the operation order may be changed, various operations may be merged, certain operations may be divided, and/or certain operations may be omitted and not performed.

As used herein, the singular forms “a”, “an” and “the” are intended to include the plural forms as well, unless the context clearly indicates otherwise. Expressions such as “first” and “second” indicate various constituent elements regardless of order and/or importance, are used for distinguishing a constituent element from another constituent element, and do not limit corresponding constituent elements. For example, a “first” constituent element may be referred to as a “second” constituent element without deviating from the scope described in the present specification, and similarly, a “second” constituent element may be referred to as a “first” constituent element. As used in this specification, a phrase of the form “at least one of A, B, or C” includes within its scope “only A”, “only B”, “only C”, “A and B”, “A and C”, “B and C” and “A, B, and C.”

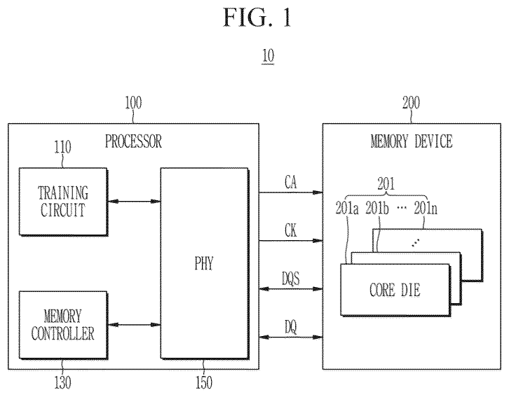

FIG. 1 is a view showing a semiconductor device according to an embodiment.

Referring to FIG. 1, a semiconductor device 10 may include a processor 100 and a memory device 200. In some embodiments, the processor 100 and the memory device 200 may be connected through a plurality of channels to exchange signals. For example, in some embodiments, the processor 100 and the memory device 200 may be connected through a through silicon via (TSV).

The memory device 200 may be a storage device based on a semiconductor element. In some embodiments, the memory device 200 may be a high bandwidth memory (HBM). In some embodiments, the memory device 200 may be a phase change random access memory (PRAM) having resistive memory cells, or a resistive random access memory (RRAM), a magnetic random access memory (MRAM), and a ferroelectric random access memory (FRAM). In some embodiments, the memory device 200 may be a dynamic random access (DRAM) device with dynamic memory cells.

The memory device 200 may include a plurality of core dies 201. For example, the plurality of core dies 201 may include a first core die 201a, a second core die 201b, . . . , to an n-th core die 201n. Each of the plurality of core dies 201 may include a memory cell for storing data.

The processor 100 may control the overall operation of the semiconductor device 10. The processor 100 may execute a program according to an application supported by the semiconductor device 10, and receive data related to the program execution from memory device 200, or transmit data corresponding to a result of the program execution to the memory device 200. The processor 100 may include various intellectual properties (IP). For example, the processor 100 may be implemented as a part of a system on chip (SoC), but embodiments are not limited thereto.

In some embodiments, the processor 100 may control the operation of the memory device 200 by providing a signal to the memory device 200. For example, the processor 100 may control the memory device 200 so that the data is stored in the memory device 200 or the data is output from the memory device 200.

The processor 100 may include a training circuit 110, a memory controller 130, and a physical layer (PHY) 150.

The training circuit 110 may determine the operation mode of the semiconductor device 10. The training circuit 110 may be implemented as hardware including an analog circuit and/or a digital circuit, or may be implemented as a software including a plurality of instructions that are executed within the processor 100. The training circuit 110 may control the semiconductor device 10 so that the semiconductor device 10 operates in a training mode or a normal mode.

When the semiconductor device 10 operates in the training mode, the training circuit 110 may determine a training value through training on the memory device 200. For example, the training circuit 110 may perform a training operation on one target core die among the plurality of core dies 201a to 201n in the memory device 200. When the semiconductor device 10 operates in the training mode, the semiconductor device 10 may perform at least one of a read training operation for a read pass between the processor 100 and the target core die, a write training operation for a write pass between the processor 100 and the target core die, or a command bus training operation for a command pass between the processor 100 and the target core die.

In some embodiments, the training circuit 110 may store information used when the semiconductor device 10 operates in the training mode. In some embodiments, the training circuit 110 may store a plurality of command sets corresponding to each training operation. In some embodiments, a command set may include at least one of an active command, a read command, a write command, or a precharge command. In some embodiments, the training circuit 110 may include information about a minimum interval between the plurality of commands included in the command set. For example, the minimum interval between the plurality of commands may be a multiple of a clock (CK). For example, in an embodiment, a first command set corresponding to a read training operation may sequentially include an active command, a read command, and a precharge command. Here, the first command set may include a first interval between the active command and the read command, and a second interval between the read command and the precharge command.

When the semiconductor device 10 performs the read training operation, the training circuit 110 may determine a reception timing of a data signal DQ so that a signal integrity or a data-eye of the data signal DQ received from the memory device 200 to the PHY 150 is optimal. The reception timing denotes a timing for the PHY 150 to sample the data signal DQ received from the memory device 200, and the time (or a timing) at which the data signal DQ is sampled may vary depending on the reception timing. The training circuit 110 may generate the reception timing information based on the determined reception timing.

When the semiconductor device 10 performs the write training operation, the training circuit 110 may determine a transmission timing of the data signal DQ so that the signal integrity or the data-eye of the data signal DQ transmitted from the PHY 150 to the memory device 200 is optimal. The transmission timing denotes a timing for the PHY 150 to transmit the data signal DQ to the memory device 200, and a time (or a timing) at which the data signal DQ is transmitted to the memory device 200 may vary depending on the transmission timing. The training circuit 110 may generate the transmission timing information based on the determined transmission timing.

When the semiconductor device 10 performs the command bus training operation, the training circuit 110 may determine a toggle timing (e.g., a rising edge and/or a falling edge) of a clock CK to optimize the signal integrity or the data-eye of a command/address signal CA transmitted from the PHY 150 to the memory device 200. The toggle timing denotes a timing for the memory device 200 to sample the command/address signal CA, and a time (or a timing) for the memory device 200 to capture the command/address signal CA may vary depending on the toggle timing. The training circuit 110 may generate a toggle timing information based on the determined toggle timing.

In an embodiment, the training circuit 110 may store the generated transmission timing information, reception timing information, and/or toggle timing information. In an embodiment, the training circuit 110 may transmit the command/address signal CA and the data signal DQ to the memory device 200 and receive the data signal DQ from the memory device 200 based on the transmission timing information, the reception timing information, and/or the toggle timing information. In some embodiments, the PHY 150 may adjust the transmitting/receiving time of the data signal DQ according to the transmission timing information or the reception timing information.

In some embodiments, upon an initialization (i.e., a boot-on) of the semiconductor device 10, the processor 100 may perform a training by performing the read training operation, the write training operation, and/or the command bus training operation on the memory device 200. In various embodiments, the processor 100 may perform the training periodically, aperiodically, and/or when a specific condition of the memory device 200 occurs.

The memory controller 130 may control the memory device 200 through the PHY 150. The memory controller 130 may generate a signal to access the memory device 200. The memory controller 130 may store the data in the memory device 200. The memory controller 130 may receive the data read from the memory device 200.

The PHY 150 may transmit/receive signals with the memory device 200 under the control of the training circuit 110 and the memory controller 130.

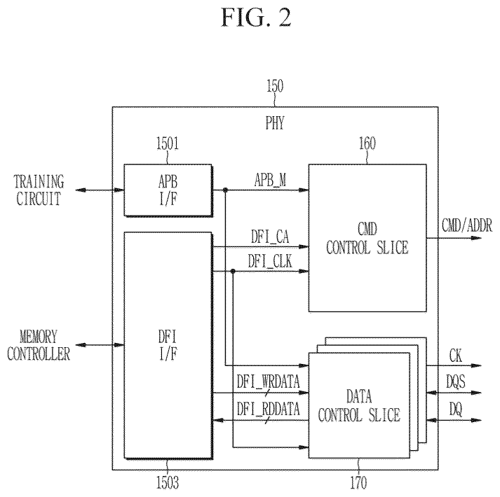

The PHY 150 may transmit the clock CK, the command/address signal CA, a data strobe signal DQS, and the data signal DQ to the memory device 200. The PHY 150 may receive the data strobe signal DQS and the data signal DQ from the memory device 200. The PHY 150 may transmit the data signal DQ to the memory device 200 based on the data strobe signal DQS, or may receive the data signal DQ from the memory device 200 based on the data strobe signal DQS. For example, the data strobe signal DQS may include the clock CK, a write clock WCK, a read clock BRCK, and a read strobe signal CRCK, etc., which will be described later with reference to FIG. 2 to FIG. 4.

In some embodiments, the PHY 150 may generate a plurality of command/address signals CA. In some embodiments, the PHY 150 may generate the plurality of clock CK and the data strobe signals DQS. In some embodiments, the PHY 150 may transmit a predetermined data signal DQ to the memory device 200.

In some embodiments, the PHY 150 may transmit the clock CK, the command/address signal CA, the data strobe signal DQS, and the data signal DQ received from the memory controller 130.

In some embodiments, the memory device 200 may sample the command/address signal CA based on the clock CK received from the processor 100. The memory device 200 may receive the data signal DQ based on the data strobe signal DQS received from the processor 100, and may transmit the data signal DQ to the processor 100 based on the data strobe signal DQS.

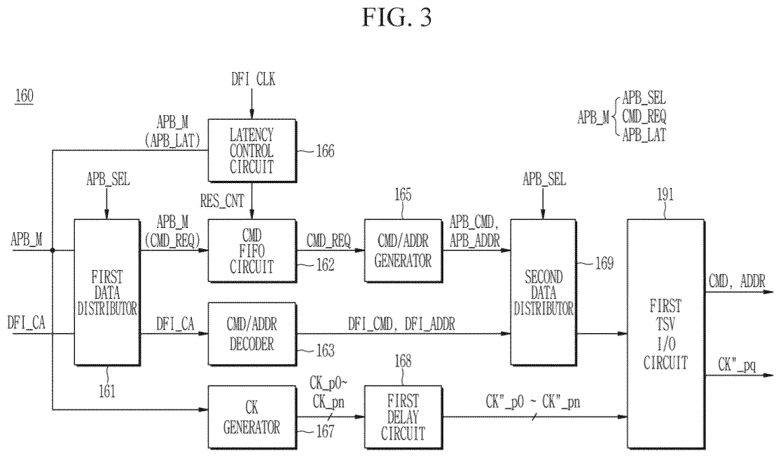

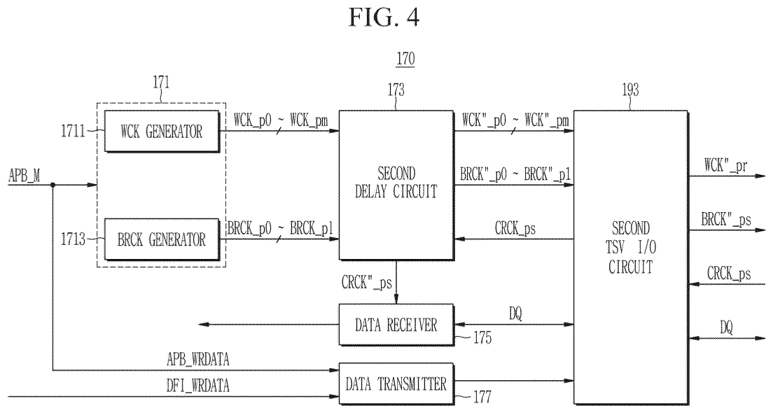

FIG. 2 is a view showing a physical layer (PHY) according to an embodiment. FIG. 3 is a view showing a command control slice according to an embodiment. FIG. 4 is a view showing a data control slice according to an embodiment.

Referring to FIG. 2, the PHY 150 may include an advanced peripheral bus (APB) interface (I/F) 1501, a DDR physical interface (DFI) interface (I/F) 1503, a command (CMD) control slice 160, and a data control slice 170.

The APB interface (I/F) 1501 may transmit/receive signals with the training circuit 110. In some embodiments, the APB interface 1501 may receive a mode signal APB_M used to train the memory device 200 from the training circuit 110. The mode signal APB_M may include information about the mode of semiconductor device 10 and information used when the semiconductor device 10 operates in the training mode.

The APB interface (I/F) 1501 may transmit the mode signal APB_M to the command control slice 160 and the data control slice 170.

The DFI interface (I/F) 1503 is capable of transmitting/receiving signals with the memory controller 130. In some embodiments, the DFI interface 1503 may receive a DFI command/address signal DFI_CA, a DFI clock DFI_CLK, and a DFI write data DFI_WRDATA from the memory controller 130. The DFI interface 1503 may transmit the DFI command/address signal DFI_CA and the DFI clock DFI_CLK to the command control slice 160. The DFI interface 1503 may transmit the DFI write data DFI_WRDATA to the data control slice 170. In some embodiments, the DFI interface 1503 may transmit the DFI read data DFI_RDDATA received from the memory device 200 through the data control slice 170 to the memory controller 130.

The command (CMD) control slice 160 may mutually communicate with a channel for the transmission of commands and/or addresses. The command control slice 160 may generate a command and address CMD/ADDR based on a mode signal APM_M. For example, when the semiconductor device 10 operates in the training mode, the command control slice 160 may generate a plurality of APB commands APB_CMD and a plurality of APB addresses APB_ADDR for the training of the memory device 200 as the command and address CMD/ADDR based on the mode signal APB_M received from training circuit 110 through the APB interface 1501. When the semiconductor device 10 operates in a normal mode, the command control slice 160 may generate the DFI command DFI_CMD and the DFI address DFI_ADDR as the command and address CMD/ADDR based on the DFI command/address signal DFI_CA received from the memory controller 130 through the DFI interface 1503.

Referring to FIG. 2 and FIG. 3 together, the command (CMD) control slice 160 may include a first data distributor 161, a CMD first in first out (FIFO) circuit 162, a command/address (CMD/ADDR) decoder 163, a command/address (CMD/ADDR) generator 165, a latency control circuit 166, a clock (CK) generator 167, a first delay circuit 168, a second data distributor 169, and a first TSV input/output (I/O) circuit 191.

The first data distributor 161 may receive the mode signal APB_M from APB interface 1501 and the DFI command/address DFI_CA from the DFI interface 1503. The first data distributor 161 may select one input from the plurality of inputs based on the mode signal APB_M to be transmitted to the corresponding configuration.

In some embodiments, the mode signal APB_M may include mode selection data APB_SEL, command generation data CMD_REQ, and latency data APB_LAT. The mode selection data APB_SEL may be a signal indicating the operation mode of semiconductor device 10. The command generation data CMD_REQ may include an information about the plurality of command sets corresponding to each of the plurality of training operations. The latency data APB_LAT may include an information about the time interval between the plurality of commands included in the command set.

For example, in some embodiments, if the mode selection data APB_SEL has a first level, the semiconductor device 10 may operate in the training mode. When the semiconductor device 10 operates in the training mode, the first data distributor 161 may select the mode signal APB_M to transmit the selected mode signal APB_M to the CMD FIFO circuit 162.

The CMD FIFO circuit 162 may receive the mode signal APB_M from the first data distributor 161 to be stored, and sequentially transmit receive the mode signal APB_M to the command/address generator 165. Specifically, the CMD FIFO circuit 162 may receive the command generation data CMD_REQ from first data distributor 161 to be stored.

The command generation data CMD_REQ may include information about the plurality of commands included in the command set. For example, as described above, when the semiconductor device 10 performs the read training operation, the command generation data CMD_REQ may include an information about the first command set sequentially including the active command, the read command, and the precharge command, and an information about the interval between the active command, the read command, and the precharge command.

In some embodiments, the CMD FIFO circuit 162 may control the timing of the command generation data CMD_REQ output to the command/address generator 165 based on a counting result RES_CNT received from the latency control circuit 166. As described later, the command/address generator 165 may generate an APB command APB_CMD and an APB address APB_ADDR based on the command generation data CMD_REQ, so the CMD FIFO circuit 162 may control the timing at which the APB command APB_CMD and the APB address APB_ADDR are output. Although not shown in FIG. 2, in some embodiments, the CMD FIFO circuit 162 may synchronize the command generation data CMD_REQ with the DFI clock DFI_CLK. The CMD FIFO circuit 162 may transmit the synchronized command generation data CMD_REQ to the command/address generator 165.

The latency control circuit 166 may generate the counting result RES_CNT based on the latency data APB_LAT. In some embodiments, the latency control circuit 166 may be a counter. The latency control circuit 166 may count a number of the rising or falling edges of the DFI clock DFI_CLK. The latency control circuit 166 may generate the counting result RES_CNT based on the counting number and the latency data APB_LAT.

The command/address (CMD/ADDR) generator 165 may generate the APB command APB_CMD and the APB address APB_ADDR based on the command generation data CMD_REQ. That is, each sequence of the APB command APB_CMD and the APB address APB_ADDR generated by the CMD FIFO circuit 162 and the command/address generator 165, and each output order of the APB command APB_CMD and the APB address APB_ADDR may be controlled based on the mode signal APB_M. The command/address generator 165 may transmit the APB command APB_CMD and the APB address APB_ADDR to the second data distributor 169.

For example, in some embodiments, if the mode selection data APB_SEL has a second level, the semiconductor device 10 may operate in a normal mode. When the semiconductor device 10 operates in the normal mode, the first data distributor 161 may select the DFI command/address DFI_CA and transmit the selected DFI command/address DFI_CA to the command/address decoder 163.

The command/address (CMD/ADDR) decoder 163 may generate the DFI command DFI_CMD and the DFI address DFI_ADDR based on the DFI command/address DFI_CA. The command/address decoder 163 may transmit the DFI command DFI_CMD and the DFI address DFI_ADDR to the second data distributor 169.

The second data distributor 169 may receive the mode signal APB_M from the APB interface 1501, the APB command APB_CMD and the APB address APB_ADDR from the command/address generator 165, and the DFI command DFI_CMD and the DFI address DFI_ADDR from the command/address decoder 163. The second data distributor 169 may select one input from the plurality of inputs based on the mode signal APB_M e.g., a mode selection data APB_SEL to be transmitted to the first TSV input/output circuit 191. In some embodiments, when the mode selection data APB_SEL has the first level, the second data distributor 169 may transmit the APB command APB_CMD and the APB address APB_ADDR to the first TSV input/output circuit 191. If the mode selection data APB_SEL has a second level, the second data distributor 169 may transmit the DFI command DFI_CMD and the DFI address DFI_ADDR to the first TSV input/output circuit 191.

The clock (CK) generator 167 may generate the clock CK output to the memory device 200 based on the mode signal APB_M. In some embodiments, the clock generator 167 may generate a plurality of clocks CK_p0 to CK_pn with different phases (n is an integer greater than 0). In some embodiments, the clock generator 167 may generate a plurality of clocks CK_p0 to CK_p3 by shifting the phase of the clock CK by 0 degrees, 90 degrees, 180 degrees, and 270 degrees, respectively, using a divider. For example, in some embodiments, the plurality of clocks CK_p0-CK_p3 may include a first clock CK_p0 corresponding to the phase 0 degrees, a second clock CK_p1 corresponding to the phase 90 degrees, a third clock CK_p2 corresponding to the phase 180 degrees, and a fourth clock CK_p3 corresponding to the phase 270 degrees. Although not shown in FIG. 3, the clock generator 167 may include a duty cycle corrector (DCC) and/or duty cycle adjuster (DCA) that adjusts the duty cycle of the clock CK.

The clock generator 167 may transmit the plurality of generated clocks CK_p0 toe CK_p3 to the first delay circuit 168. In some embodiments, the clock generator 167 may transmit one clock CK_pq (q is an integer of 0 or more and n or less) among the plurality of clocks CK_p0 to CK_pn to the first delay circuit 168.

When the semiconductor device 10 operates in the training mode, first delay circuit 168 may apply the delay to the signal received from the clock generator 167. In some embodiments, the first delay circuit 168 may include a delay locked loop (DLL) including a plurality of delay cells. In some embodiments, the first delay circuit 168 may store a plurality of delay codes having predetermined delay lengths based on a unit time delayed by one delay cell. For example, the first delay code may correspond to the delay of the first time length, and the second delay code may correspond to the delay of the second time length. In some embodiments, the first delay circuit 168 may transmit a clock signal to which the delay is applied to the memory device 200 through the first TSV input/output circuit 191.

The first delay circuit 168 may apply the delay to each of the plurality of clocks CK_p0 to CK_p3 received from the clock generator 167. The first delay circuit 168 may generate a plurality of delayed clocks CK″_p0 to CK″_p3 by applying a different length of the delay to each of the plurality of clocks CK_p0 to CK_p3. For example, the first delay circuit 168 may generate a first delayed clock CK″_p0 by applying the delay corresponding to the first delay code to the clock CK_p0 having the first phase. The first delay circuit 168 may transmit the plurality of delayed clocks CK″_p0 to CK″_p3 to the first TSV input/output circuit 191. In some embodiments, the first delay circuit 168 may transmit the delayed clock CK″_pq to the first TSV input/output circuit 191 by applying the delay to the clock CK_pq (q is an integer of 0 or more and n or less).

The first TSV input/output circuit 191 may transmit the signal received from the command/address generator 165 to the memory device 200 as the command and address CMD/ADDR. The first TSV input/output circuit 191 may transmit the signal received from the command/address decoder 163 to the memory device 200 as the command and address CMD/ADDR.

Again referring to FIG. 2, the data control slice 170 may mutually communicate with the channel for transmitting/receiving data. When the semiconductor device 10 operates in the training mode, the data control slice 170 may generate a plurality of clock signals used for the training of the memory device 200 based on the mode signal APB_M received from the training circuit 110 through the APB interface 1501. When the semiconductor device 10 operates in the normal mode, the data control slice 170 may receive a DFI clock DFI_CLK and a DFI write data DFI_WRDATA received from the memory controller 130 through the DFI interface 1503. The data control slice 170 may transmit the DFI read data DFI_RDDATA received from the memory device 200 to the DFI interface 1503.

Referring to FIG. 2 and FIG. 4 together, the data control slice 170 may include a clock signal generator 171, a second delay circuit 173, a data receiver 175, a data transmitter 177, and a second TSV IO 193.

The clock signal generator 171 may generate a plurality of clock signals required when operating the semiconductor device 10 in the training mode. In some embodiments, the clock signal generator 171 may include a write clock WCK generator 1711 and a read clock BRCK generator 1713.

The write clock WCK generator 1711 may generate a write clock WCK output to the memory device 200 based on the mode signal APB_M. The write clock WCK may be a signal for transmitting the data signal DQ to the memory device 200 (more specifically, for sampling or latching). The write clock generator 1711 may generate a plurality of write clocks WCK_p0 to WCK_pm (m is an integer greater than 0) having a plurality different phases. In some embodiments, the clock generator 167 may generate a plurality of clocks WCK_p0 to WCK_p3) by shifting the phase of the write clock WCK by 0 degrees, 90 degrees, 180 degrees, and 270 degrees, respectively, using a divider. For example, in some embodiments, the plurality of write clock WCK_p0 to WCK_p3 may include a first write clock WCK_p0 corresponding to the phase 0 degrees, a second write clock WCK_p1 corresponding to the phase 90 degrees, a third write clock WCK_p2 corresponding to the phase 180 degrees, and a fourth write clock WCK_p3 corresponding to the phase 360 degrees. Although not shown in FIG. 4, in some embodiments, the write clock generator 1711 may include a DCC and/or a DCA that adjusts the duty cycle of the write clock WCK.

In some embodiments, the plurality of write clocks WCK_p0 to WCK_pm may correspond to the phases of 0 degrees, 90 degrees, 180 degrees, 360 degrees, 450 degrees, 540 degrees, and 720 degrees, respectively.

The write clock WCK generator 1711 may transmit the plurality of generated write clocks (WCK_p0 to WCK_pm) to the second delay circuit 173.

In some embodiments, the write clock WCK generator 1711 may generate one write clock WCK_pr (r is an integer of 0 or more and m or less) among the plurality of write clocks WCK_p0 to WCK_pm based on the mode signal APB_M as a target write clock. The write clock generator 1711 may transmit the target write clock to the second delay circuit 173.

In some embodiments, the clock CK and the write clock WCK may be generated based on the same phase lock loop (PLL). In some embodiments, the clock CK may have a smaller frequency than the write clock WCK.

The read clock BRCK generator 1713 may generate the read clock BRCK output to the memory device 200 based on the mode signal APB_M.

The read clock BRCK generator 1713 may generate a plurality of read clocks BRCK_p0 to BRCK_pl (l is an integer greater than 0) having a plurality of different phases. In some embodiments, the read clock generator 1713 may generate a plurality of clocks BRCK_p0 to BRCK_p3 by shifting the phases of the clock CK by 0 degrees, 90 degrees, 180 degrees, and 270 degrees, respectively, using a divider. For example, the plurality of read clocks BRCK_p0 to BRCK_p3 may include a first read clock BRCK_p0 corresponding to the phase 0 degrees, a second read clock BRCK_p1 corresponding to the phase 90 degrees, a third read clock BRCK_p2 corresponding to the phase 180 degrees, and a fourth read clock BRCK_p3 corresponding to the phase 360 degrees. Although not shown in FIG. 4, in some embodiments, the read clock generator 1713 may include a DCC and/or a DCA that adjusts the duty cycle of the read clock BRCK.

The read clock BRCK generator 1713 may transmit the plurality of generated read clocks BRCK_p0 to BRCK_p1 to the second delay circuit 173.

In some embodiments, the read clock BRCK generator 1713 may generate one read clock BRCK_ps (s is an integer between 0 and 1 and below) among the plurality of read clocks BRCK_p0 to BRCK_p1 as a target read clock based on the mode signal APB_M. The read clock generator 1713 may transmit the target read clock to the second delay circuit 173.

When the semiconductor device 10 operates in the training mode, the second delay circuit 173 may apply the delay to the signal received from the clock signal generator 171. In some embodiments, the second delay circuit 173 may include a DLL including a plurality of delay cells. In some embodiments, the second delay circuit 173 may store a plurality of delay codes having predetermined delay lengths based on the unit time delayed by one delay cell. For example, in some embodiments, a first delay code may correspond to a delay of a first time length, and a second delay code may correspond to a delay of a second time length. In some embodiments, the second delay circuit 173 may transmit a plurality of clock signals to which the delay is applied to the memory device 200 through the second TSV input/output circuit 193.

The second delay circuit 173 may apply the delay to each of the plurality of write clocks WCK_p0 to WCK_p3 received from the write clock generator 1711. The second delay circuit 173 may generate a plurality of delayed write clocks WCK″_p0 to WCK″_p3 by applying the delays of different lengths to each of the plurality of write clocks WCK_p0 to WCK_p3. For example, the second delay circuit 173 may generate a delayed first write clock WCK″_p0 by applying a delay corresponding to the first delay code to the write clock WCK_p0 having the first phase. The second delay circuit 173 may transmit the plurality of delayed write clocks WCK″_p0 to WCK″_p3 to the second through electrode input/output circuit 193. In some embodiments, the second delay circuit 173 may transfer the delayed write clock WCK″_pr to the second TSV input/output circuit 193 by applying a delay to the write clock WCK_pr (r is an integer between 0 and m).

The second delay circuit 173 may apply the delay to each of the plurality of read clocks BRCK_p0 to BRCK_p3 received from the read clock generator 1713. The second delay circuit 173 may generate a plurality of delayed read clocks BRCK″_p0 to BRCK″_p3 by applying delays of different lengths to each of the plurality of read clocks BRCK_p0 to BRCK_p3. For example, the second delay circuit 173 may generate a delayed first read clock BRCK″_p0 by applying the delay corresponding to the first delay code to the read clock BRCK_p0 having the first phase. The second delay circuit 173 may transmit the plurality of delayed read clocks BRCK″_p0 to BRCK″_p3 to the second through electrode input/output circuit 193. In some embodiments, the second delay circuit 173 may transmit a delayed read clock BRCK″_ps in which a delay is applied to the read clock BRCK_ps (s is an integer between 0 and 1) to the second TSV input/output circuit 193.

FIG. 4 shows that the plurality of write clocks WCK_p0 to WCK_pm and the plurality of read clocks BRCK_p0 to BRCK_p1 are transmitted to the second delay circuit 173, and the plurality of delayed write clocks WCK″_p0 to WCK″_pm and the plurality of delayed read clocks BRCK″_p0 to BRCK″_p1 are transmitted to the second TSV input/output circuit 193, but embodiments are not limited thereto and, in some embodiments, one write clock WCK_pr of the plurality of write clocks WCK_p0 to WCK_pm and one read clock BRCK_ps of the plurality of read clocks BRCK_p0 to BRCK_p1 may be transmitted to the second delay circuit 173, and one delayed write clock WCK″_pr and one delayed read clock BRCK″_ps may be transmitted to the second TSV input/output circuit 193.

The second through electrode input/output (TSV I/O) circuit 193 may transmit the signal received from the second delay circuit 173 or the data transmitter 177 to the memory device 200. The second through electrode input/output circuit 193 may transmit the signal received from the memory device 200 to the data receiver 175 or the second delay circuit 173.

In some embodiments, when the processor 100 performs a write operation, the second TSV input/output circuit 193 may transmit the write data received from the data transmitter 177 to the memory device 200 as a data signal DQ. The second TSV input/output circuit 193 may transmit the delayed write clock WCK″_pr along with the data signal DQ.

In some embodiments, when the processor 100 performs a read operation, the second TSV input/output circuit 193 may transmit a delayed read clock BRCK″_ps to the memory device 200. The second TSV input/output circuit 193 may receive data corresponding to the read operation from the memory device 200 as a data signal DQ, and receive a read strobe signal CRCK_ps generated based on delayed read clock BRCK″_ps along with the data signal DQ. The read strobe signal CRCK_ps may be a signal for receiving the data signal DQ from the memory device 200. The second TSV input/output circuit 193 may transmit the read strobe signal CRCK_ps to the second delay circuit 173. Additionally, the second TSV input/output circuit 193 may transmit the read data to the data receiver 175.

The second delay circuit 173 may generate a delayed read strobe signal CRCK″_ps by applying a delay to the received read strobe signal CRCK″_ps. The second delay circuit 173 may transmit the delayed read strobe signal CRCK″_ps to the data receiver 175.

The data receiver 175 may receive the read data from the second TSV input/output circuit 193. The data receiver 175 may sample the read data based on the delayed read strobe signal CRCK″_ps received from the second delay circuit 173. The PHY 150 may sample the read data by using the read strobe signal CRCK″_ps generated based on the plurality of delayed read clocks BRCK″_p0 to BRCK″_p1 and find the optimal sampling point to latch the read data.

In some embodiments, the data receiver 175 may receive the read data from the memory device 200 during the read operation when the semiconductor device 10 operates in a normal mode. The data receiver 175 may sample the read data based on a reception timing information obtained by the semiconductor device 10 through the training.

The data receiver 175 may transmit the sampled read data to the training circuit 110. The data receiver 175 may transmit the sampled read data to the memory controller 130.

The data transmitter 177 may transmit a training pattern APB_WRDATA to the second TSV input/output circuit 193 when the semiconductor device 10 operates in a training mode. The data transmitter 177 may transmit a DFI write data DFI_WRDATA received from the DFI interface 1503 to the second TSV input/output circuit 193 when the semiconductor device 10 operates in a normal mode.

As a number of stacked memory chips sharing a signal path using a through electrode increases, a load on the signal path may increase. As the load on the signal path increases, a rising time and falling time of the transmitted signal increases, which may prevent the signal from being transmitted normally. Additionally, the TSV delay time may be required to pass through the through electrode. The TSV delay time may vary depending on various factors. For example, the TSV delay time may vary due to factors that are difficult to be predicted, such as differences in parasitic parameters or processes. Therefore, the time taken to transmit a data between the processor 100 and the memory device 200 may be uncertain. Therefore, a performance may be deteriorated during the data transmission within the semiconductor device 10.

Therefore, the training circuit 110 according to some embodiments may detect an optimal condition for transmitting/receiving signals between the processor 100 and the memory device 200 through the training operation for the semiconductor device 10 and secure a data reliability.

In some embodiments, the first delay circuit 168 and the second delay circuit 173 may be controlled by the training circuit 110 and/or the memory controller 130. The training circuit 110 may calculate a valid window margin (VWM) by comparing the write data and the read data. In some embodiments, the valid window margin may denote a maximum section in which the data receiver 175 may detect the read data output from the memory device 200 by using the read strobe signal CRCK_ps output from the memory device 200. In some embodiments, the valid window margin may denote a maximum section in which the memory device 200 may detect the write data output from the data control slice 170 by using delayed write clock WCK″_pr output from the processor 100. For example, the valid window margin calculated by the semiconductor device 10 operating in the training mode may be stored in the training circuit 110. Training circuit 110 may determine the optimal delay code detected for the clock CK based on the valid window margin, the optimal delay code detected for the write clock WCK, and/or the optimal delay code detected for the read strobe signal CRCK based on the read clock BRCK.

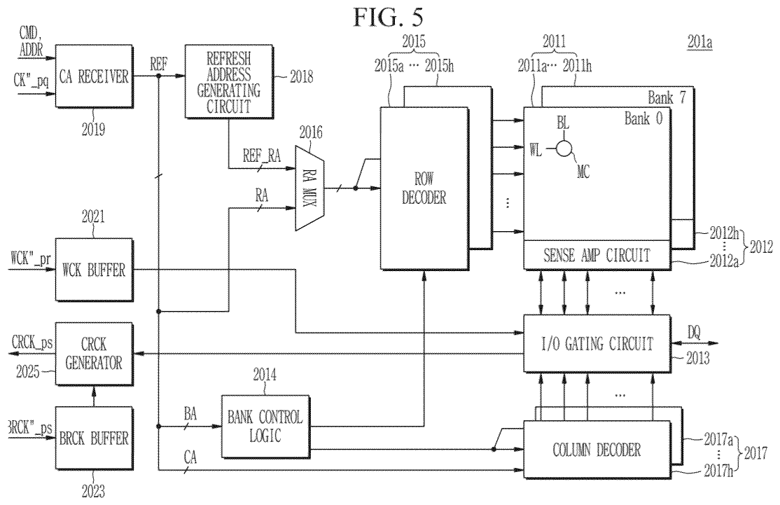

FIG. 5 is a view showing a configuration of a core die according to an embodiment.

Specifically, FIG. 5 is the view showing the configuration of the first core die 201a among the plurality of core dies 201. However, it will be noted that a similar description applies to the remaining ones of the plurality of core dies 201. Referring to FIG. 5, the first core die 201a may include a memory cell array 2011, a sense amplifier (AMP) circuit 2012, an input/output (I/O) gating circuit 2013, bank control logic 2014, a row decoder 2015, a row address multiplexer (RA MUX) 2016, a column decoder 2017, a refresh address generating circuit 2018, a command and address (CA) receiver 2019, a write clock (WCK) buffer 2021, a read clock (BRCK) buffer 2023, and a read strobe signal (CRCK) generator 2025.

The memory cell array 2011 may include a plurality of memory cells MC. In some embodiments, the memory cell array 2011 may include a plurality of memory banks 2011a to 2011h. FIG. 5 shows eight memory banks BANK0 to BANK7, 2011a to 2011h, but the number of the memory banks is not limited to eight. Each memory bank 2011a to 2011h may include a plurality of rows, a plurality of columns, and a plurality of memory cells MC arranged at the intersections of the plurality of rows and the plurality of columns. The memory cell MC may include one transistor and one capacitor. In some embodiments, the plurality of rows may be defined by a plurality of word lines WL, and the plurality of columns may be defined by a plurality of bit lines BL.

The command and address (CA) receiver 2019 may receive a command CMD and an address ADDR based on the clock CK received from the processor 100. In some embodiments, when semiconductor device 10 operates in a training mode, the command CMD may be an APB command APB_CMD received from the first TSV input/output circuit 191, and the address ADDR may be an address APB_ADDR received from the first TSV input/output circuit 191. In some embodiments, when the semiconductor device 10 operates in a normal mode, the command CMD may be a DFI command DFI_CMD received from the first TSV input/output circuit 191, and the address ADDR may be a DFI address DFI_ADDR.

In some embodiments, the command and address (CA) receiver 2019 is capable of decoding activation commands, read commands, write commands, precharge commands, etc.

In some embodiments, the command and address (CA) receiver 2019 may generate a refresh instruction REF by decoding the DFI command (DFI_CMD) received from a memory controller (e.g., 130 in FIG. 1).

In some embodiments, the address ADDR may include a row address RA indicating a row and a column address CA indicating a column of the memory cell array 2011. The row address RA may be provided to the row decoder 2015, and the column address CA can be provided to the column decoder 2017. The row address RA may be provided to the refresh address generating circuit 2018. In some embodiments, the row address RA may be provided to the row decoder 2015 or may be provided to the row decoder 2015 through the row address multiplexer 2016. In some embodiments, the address (ADDR) may further include a bank address BA indicating a memory bank.

The refresh address generating circuit 2018 may control the refresh of rows in the memory cell array 2011. In some embodiments, the refresh address generating circuit 2018 may generate a row address REF_RA to be refreshed based on the refresh instruction REF. The refresh address generating circuit 2018 can transmit the row address REF_RA to be refreshed to the row address multiplexer 2016.

The row address multiplexer (RA MUX) 2016 may receive the row address RA from the command and address receiver 2019 and the row address REF_RA to be refreshed from the refresh address generating circuit 2018. The row address multiplexer 2016 may selectively output the row address RA received from address buffer 230 and the row address REF_RA received from the refresh address generating circuit 2018 to the row decoder 2015.

In some embodiments, the row decoder 2015 may select the row to be activated among the plurality of rows of the memory cell array 2011 based on the row address RA or REF_RA. In some embodiments, the row decoder 2015 may select the row to be activated among the plurality of rows in the dummy cell array 215 based on row address RA. For this purpose, the row decoder 2015 may apply a driving voltage to the word line corresponding to the row to be activated. In some embodiments, the plurality of row decoders 2015a to 2015h may be provided to the plurality of corresponding memory banks 2011a to 2011h, respectively.

The bank control logic 2014 may receive the bank address BA from the command and address receiver 2019 and generate a bank control signal in response to the bank address BA. In response to the bank control signal, the row decoder 2015 corresponding to the bank address BA among the plurality of row decoders 2015a to 2015h may be activated, and the column decoder corresponding to the bank address BA among the plurality of column decoders 2017a to 2017h 2017 may be activated.

The column decoder 2017 may select the column to be activated among the plurality of columns of memory cell arrays 2011 based on the column address CA. For this purpose, the column decoder 2017 may activate the sense amplifier circuit 2012 corresponding to the column address CA through the I/O gating circuit 2013. In some embodiments, a plurality of column decoder 2017a to 2017h corresponding to the plurality of memory banks 2011a to 2011h may be provided.

The write clock (WCK) buffer 2021 may receive the delayed write clock WCK″_pr from the processor 100. The write clock buffer 2021 may provide the write clock WCK″_pr received during the write operation for the core die 201a to the I/O gating circuit 2013.

The read clock (BRCK) buffer 2023 may receive the delayed read clock BRCK″_ps from the processor 100. The read clock buffer 2023 may transmit the delayed read clock BRCK″_ps to the read strobe signal generator 2025.

The read strobe signal (CRCK) generator 2025 may generate the read strobe signal CRCK_ps based on the delayed read clock BRCK″_ps. The read strobe signal (CRCK) generator 2025 may output the read strobe signal CRCK_ps to the processor 100.

In some embodiments, the I/O gating circuit 2013 may gate the data signal DQ with the processor 100. In some embodiments, the I/O gating circuit 2013 may include a receiver that receives the write data and a transmitter that outputs the read data.

The I/O gating circuit 2013 may include a data latch for storing a data read from the memory cell array 2011 and a write driver for writing a data to the memory cell array 2011. The data read from the memory cell array 2011 may be sensed by the sense amplifier circuit 2012 and stored in the I/O gating circuit (2013, e.g., the data latch). In some embodiments, the plurality of sense amplifier circuits 2012a to 2012h respectively corresponding to the plurality of memory banks 2011a to 2011h may be provided.

In some embodiments, the I/O gating circuit 2013 may receive the write data from the processor 100 or output the read data to the processor 100. During the write operation on the core die 201a, the I/O gating circuit 2013 may latch the write data based on the delayed write clock WCK″_pr received from the write clock buffer 2021. During the read operation on the core die 201a, the I/O gating circuit 2013 may transmit the read data to the processor 100 along with the transmission of the read strobe signal CRCK_ps.

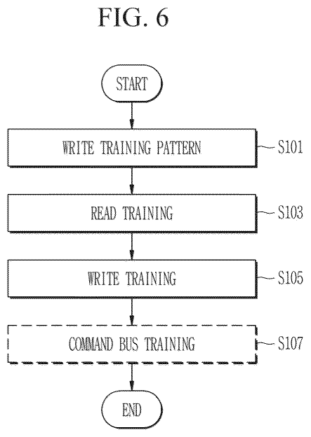

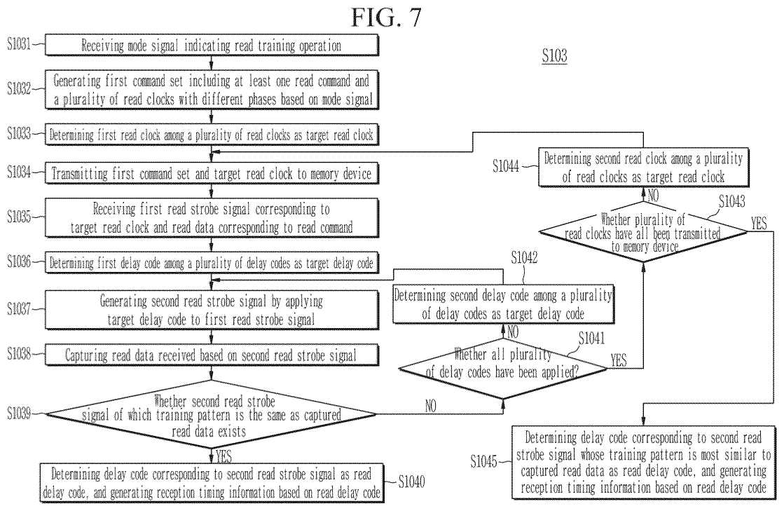

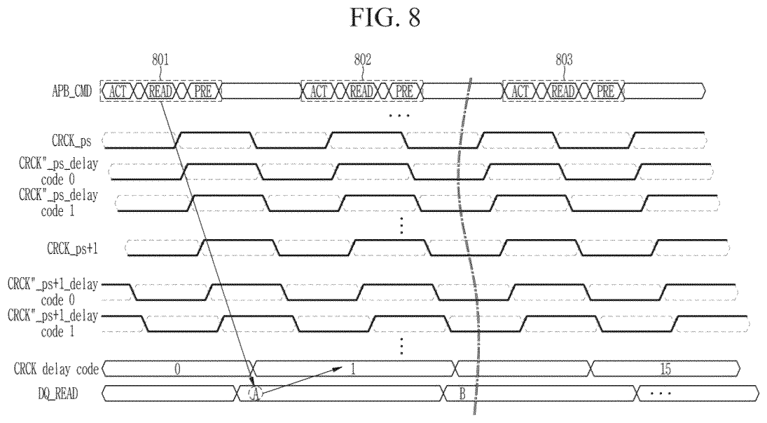

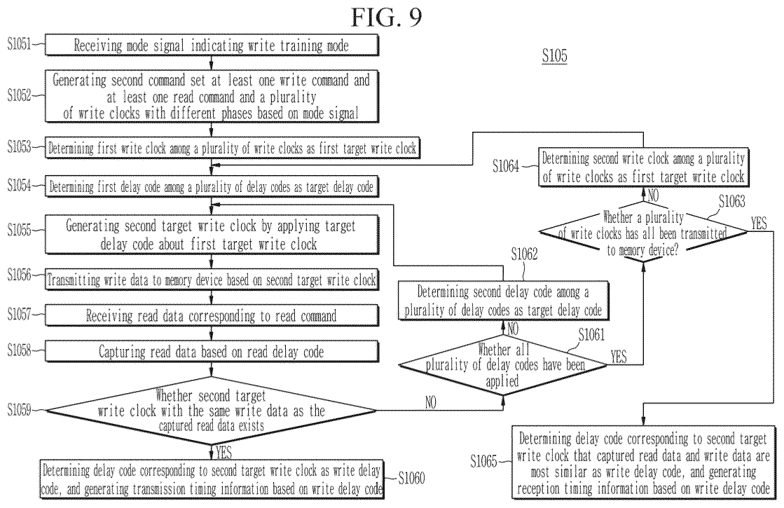

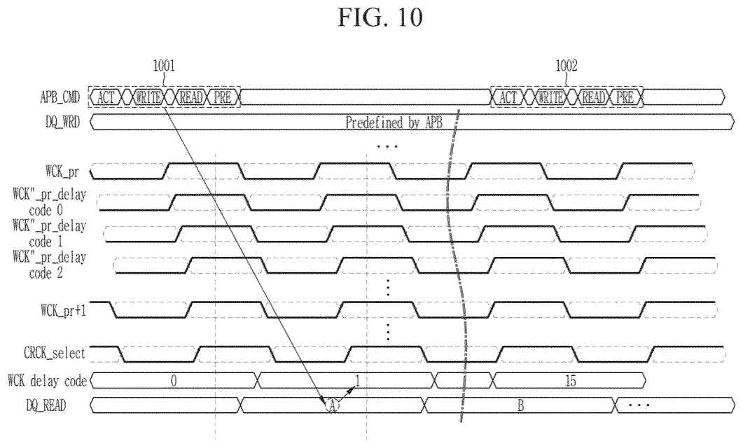

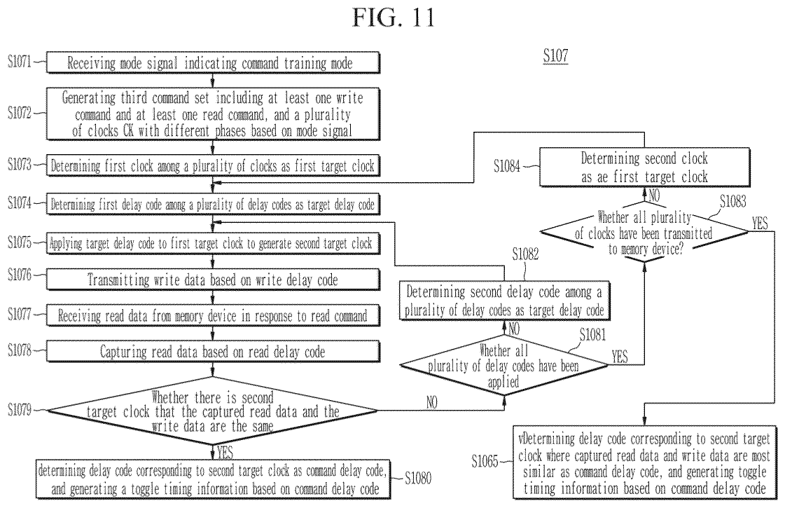

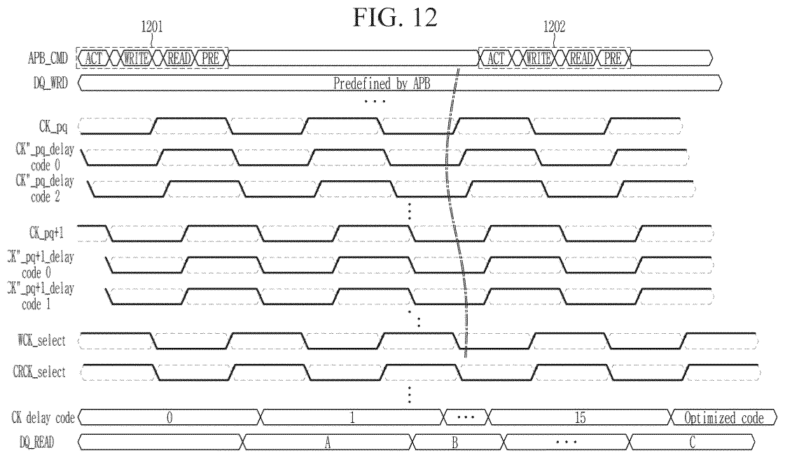

FIG. 6 is a view showing a method in which a semiconductor device operates in a training mode according to an embodiment. FIG. 7 is a view that specifically shows a reading training operation in the method of FIG. 6, according to an embodiment. FIG. 8 is an exemplary timing diagram of signals between a processor and a memory device when performing a read training operation, according to an embodiment. FIG. 9 is a view that specifically shows a writing training operation in the method of FIG. 6, according to an embodiment. FIG. 10 is an exemplary timing diagram of signals between a processor and a memory device when performing a write training operation, according to an embodiment. FIG. 11 is a view that specifically shows a command bus training operation in the method of FIG. 6, according to an embodiment. FIG. 12 is an exemplary timing diagram of signals between a processor and a memory device when performing a command bus training operation, according to an embodiment.

The semiconductor device 10 may perform an initialization. For example, when the semiconductor device 10 is powered on, the processor 100 and the memory device 200 may perform the initialization according to an initialization method. In some embodiments, the initialization method may be predetermined. During the initialization, the processor 100 may provide a power voltage to the memory device 200, perform various initial operations, and read or set information from the memory device 200. In some embodiments, during the initialization, the semiconductor device 10 may operate in the training mode.

As illustrated in FIG. 6, the processor 100 may write a training pattern to the memory device 200 (S101).

In some embodiments, the processor 100 may write the training pattern to the memory device 200 by using a low frequency write clock WCK. For example, the processor may write the training pattern to the memory device 200 by using the write clock WCK with the frequency of about 100 Mbps or less. The processor 100 may write the training pattern to the memory device 200 by using the low-frequency write clock WCK.

The processor 100 performs a read training operation on the memory device 200 (S103).

For example, in some embodiments, the processor 100 may determine the reception timing for the data signal DQ so that the signal integrity or the data-eye of the data signal DQ received from the memory device 200 is optimal, and generate reception timing information.

Referring to FIG. 7 and FIG. 8 together, the PHY 150 receives a mode signal APB_M indicating a read training operation from the training circuit 110 (S1031).

The PHY 150 generates a first command set including at least one read command and a plurality of read clocks BRCK with different phases based on the mode signal APB_M (S1032).

In some embodiments, the training circuit 110 may pre-store a first command set corresponding to the read training operation. For example, in some embodiments, as shown in FIG. 8, the plurality of first command sets 801, 802, and 803 may each include an active command, a read command, and a precharge command. In some embodiments, the PHY 150 may generate a plurality of read clocks BRCK_p0 to BRCK_p1 with different phases.

The training circuit 110 determines the first read clock BRCK_ps among the plurality of read clocks BRCK_p0 to BRCK_p1 as a target read clock (S1033).

The PHY 150 may generate the first read clock BRCK_ps based on the mode signal APB_M.

The PHY 150 transmits the first command set and the target read clock BRCK_ps to the memory device 200 (S1034).

In some embodiments, the PHY 150 may sequentially transmit the plurality of commands (the active command, the read command, and the precharge command) included in the first command set to the memory device 200. In some embodiments, the PHY 150 may transmit the target read clock BRCK_ps to the memory device 200. The memory device 200 may generate the first read strobe signal CRCK_ps based on the target read clock BRCK_ps. The memory device 200 may transmit the first read strobe signal CRCK_ps to the PHY 150.

The PHY 150 receives a first read strobe signal CRCK_ps and a read data corresponding to the read command from the memory device 200 (S1035).

As shown in FIG. 8, the memory device 200 may transmit A, which is the read data corresponding to the first read strobe signal CRCK_ps and the read command, to the PHY 150.

The training circuit 110 determines the first delay code among the plurality of delay codes as the target delay code (S1036).

In some embodiments, the training circuit 110 may pre-store a plurality of delay codes corresponding to the read training operation. The PHY 150 may obtain an information about the plurality of delay codes based on the mode signal APB_M.

The PHY 150 generates a second read strobe signal CRCK″_ps by applying the target delay code to the first read strobe signal CRCK_ps based on the mode signal APB_M (S1037).

In FIG. 8, the PHY 150 may generate a second read strobe signal CRCK″_ps_delay code 0 by applying the first delay code CRCK delay code 0.

The PHY 150 captures the read data received from the memory device 200 based on the second read strobe signal CRCK″_ps (S1038).

In FIG. 8, the PHY 150 may capture the read data A based on the second read strobe signal CRCK″_ps_delay code 0.

The PHY 150 may transmit the captured read data to the training circuit 110.

The training circuit 110 determines whether the second read strobe signal CRCK″ of which the training pattern is the same as the captured read data exists (S1039).

In some embodiments, the PHY 150 may sample the read data based on the second read strobe signal CRCK″_ps. The PHY 150 may transmit the captured read data to the training circuit 110. The training circuit 110 may compare the captured read data and the training pattern.

If there is the second read strobe signal CRCK″_ps in which the captured read data and the training pattern are the same (S1039, YES), the training circuit 110 determines the delay code corresponding to the second read strobe signal CRCK″_ps as the read delay code, and performs a reception timing information generation based on the read delay code (S1040).

In some embodiments, the training circuit 110 may determine the first delay code as the read delay code. In some embodiments, the training circuit 110 may generate the reception timing information based on the read clock BRCK_ps and first delay code corresponding to the second read strobe signal CRCK″_ps. Thereafter, processor 100 may perform the read operation on the memory device 200 based on reception timing information.

If there is no second read strobe signal CRCK″_ps in which the captured read data and the training pattern are the same (S1039, NO), the training circuit 110 determines whether all of the plurality of delay codes have been applied to the first read strobe signal CRCK_ps (S1041).

The training circuit 110 may determine whether each of the plurality of delay codes has been applied to the first read strobe signal CRCK_ps as a target delay code.

If it is determined that all of the plurality of delay codes have not been applied (S041, NO), the training circuit 110 determines the second delay code among the plurality of delay codes as the target delay code (S1042), and the processor 100 returns to operation S1037.

In other words, the training circuit 110 may generate the second read strobe signal CRCK″_ps by applying the unapplied delay code among the plurality of delay codes as the target delay code to the first read strobe signal CRCK_ps.

As shown in FIG. 8, the PHY 150 may generate a second read strobe signal CRCK″_ps_delay code 1 in which the second delay code CRCK delay code 1 is applied. The PHY 150 may capture the read data based on the second read strobe signal CRCK″_ps_delay code 1. The training circuit 110 determines whether the read data captured based on the second read strobe signal CRCK″_ps_delay code 1 and the training pattern are the same. Until the second read strobe signal with the same training pattern as the captured read data exists, the PHY 150 may perform an operation of generating a plurality of second read strobe signals CRCK″_ps_delay code 2 to CRCK″_ps_delay code 15 by applying each of the plurality of delay codes CRCK delay code 2 to CRCK delay code 15, and capturing the read data based on the plurality of second read strobe signals CRCK″_ps_delay code 2 to CRCK″_ps_delay code 15.

If it is determined that all of the plurality of delay codes have been applied (S1041, YES), the training circuit 110 determines whether the plurality of read clocks BRCK_p0 to BRCK_p1 have all been transmitted to the memory device 200 (S1043).

The training circuit 110 may determine whether each of the plurality of read clocks BRCK_p0 to BRCK_p1 has been transmitted to the memory device 200 as the target read clock.

If it is determined that all of the plurality of read clocks have not been transmitted to the memory device 200 (S1043, NO), the training circuit 110 determines the second read clock among the plurality of read clocks as the target read clock (S1044).

The training circuit 110 may determine the second read clock (BRCK_ps 1), which has the different phase from the first read clock BRCK_ps, as the target read clock.

The processor 100 may return to operation S1034.

Referring to FIG. 8, the PHY 150 may receive the first read strobe signal CRCK_ps 1 in response to the second read clock BRCK_ps 1. The PHY 150 may generate a second read strobe signal CRCK″_ps 1_delay code 0 by applying the first delay code CRCK delay code 0. The PHY 150 may capture the read data based on the second read strobe signal CRCK″_ps 1_delay code 0. The training circuit 110 determines whether the read data captured based on the second read strobe signal CRCK″_ps 1_delay code 0 and the training pattern are the same. Until the second read strobe signal with the same training pattern as the captured read data exists, the PHY 150 may perform the operation of generating a plurality of second read strobe signals CRCK″_ps 1_delay code 1 to CRCK″_ps 1_delay code 15 by applying each of the plurality of delay codes (CRCK delay code 1 to CRCK delay code 15), and capturing the read data based on the plurality of second read strobe signals CRCK″_ps 1_delay code 1 to CRCK″_ps 1_delay code 15.

If it is determined that the plurality of read clocks have all been transmitted to the memory device 200 (S1043, YES), the training circuit 110 determines the delay code corresponding to the second read strobe signal CRCK″_ps whose the training pattern is most similar to the captured read data as the read delay code, and generates the reception timing information based on the read delay code (S1045).

In FIG. 8, for better understanding and ease of description, it is shown that the plurality of read strobe signals (CRCK_ps, CRCK″_ps_delay code 0, CRCK″_ps_delay code 1, . . . , CRCK_ps+1, CRCK″_ps+1_delay code 0, CRCK″_ps+1_delay code 1, etc.) are generated at the same timing, but embodiments are not limited to this and, in some embodiments, each read strobe signal may be generated at a different time. For example, in an embodiment, the first read strobe signal CRCK_ps 1 may be generated after the processor 100 transmits the first command set 802 to the memory device 200.

Again referring to FIG. 6, the processor 100 performs write training on the memory device 200 (S105).

For example, the processor 100 may determine the transmission timing for the data signal DQ so that the signal integrity or the data-eye of the data signal DQ transmitted to the memory device 200 is optimal, and generate the transmission timing information.

Referring to FIG. 9 and FIG. 10 together, the PHY 150 receives the mode signal APB_M indicating the write training operation from the training circuit 110 (S1051).

The PHY 150 generates a second command set including at least one write command and at least one read command and a plurality of write clocks WCK with different phases based on the mode signal APB_M (S1052).

In some embodiments, the training circuit 110 may pre-store the second command set corresponding to the write training operation. For example, as shown in FIG. 10, the plurality of second command sets 1001 and 1002 may each include an active command, a write command, a read command, and a precharge command. In some embodiments, the PHY 150 may generate a plurality of write clocks WCK_p0 to WCK_pm with the different phases.

The training circuit 110 determines the first write clock WCK_pr among the plurality of write clocks WCK_p0 to WCK_pm as the first target write clock (S1053).

The PHY 150 may generate the first write clock WCK_pr based on the mode signal APB_M.

The training circuit 110 determines the first delay code among the plurality of delay codes as the target delay code (S1054).

In some embodiments, the training circuit 110 may pre-store the plurality of delay codes corresponding to the write training operation. The PHY 150 may obtain the information about the plurality of delay codes based on the mode signal APB_M.

In FIG. 10, the training circuit 110 may determine the first delay code WCK delay code 0 as the target delay code.

The PHY 150 generates the second target write clock by applying the target delay code about the first target write clock (S1055).

In FIG. 10, the PHY 150 may generate a second target write clock WCK″_pr_delay code 0 to which the first delay code (WCK delay code 0 is applied.

The PHY 150 transmits the write data to the memory device 200 based on the second target write clock WCK″_pr_delay code 0 (S1056).

The PHY 150 receives the read data corresponding to the read command (S1057).

The PHY 150 captures the read data based on the read delay code (S1058).

In some embodiments, the read delay code may be a code determined through the read training operation (S103). In FIG. 10, the PHY 150 may capture the read data based on the optimal read strobe signal CRCK_select to which the read delay code determined through the read training operation (S103) is applied.

The PHY 150 may transmit the captured read data to the training circuit 110.

The training circuit 110 determines whether the second target write clock with the same write data as the captured read data exists (S1059).

If there is the second target write clock that the captured read data and the write data are the same (S1059, YES), the training circuit 110 determines the delay code corresponding to the second target write clock as the write delay code, and generates the transmission timing information based on the write delay code (S1060).

In some embodiments, the training circuit 110 may determine the first delay code as the write delay code. In some embodiments, the training circuit 110 may generate the transmission timing information based on the read clock WCK_ps and the first delay code corresponding to the second target write clock WCK″_pr. Thereafter, the processor 100 may perform the write operation on the memory device 200 based on the transmission timing information.

If there is no second target write clock where the captured read data and write data are the same (S1059, NO), the training circuit 110 determines whether all of the plurality of delay codes have been applied (S1061).

The training circuit 110 may determine whether each of the plurality of delay codes has been applied to the first write clock WCK_pr as the target delay code.

If all of the plurality of delay codes have not been applied (S1061, NO), the training circuit 110 determines the second delay code among the plurality of delay codes as the target delay code (S1062) and the process returns to operation S1055.

In other words, the training circuit 110 may generate the second write clock WCK″_pr by applying the unapplied delay code among the plurality of delay codes to the first write clock WCK″_pr as the target delay code.

As shown in FIG. 10, the PHY 150 may generate the second write clock WCK″_pr_delay code 2 that the second delay code WCK delay code 2 is applied. The PHY 150 may capture the read data based on the read strobe signal CRCK_select. The training circuit 110 determines whether the read data captured based on the read strobe signal CRCK_select and the write data are the same. Until there is the second target write clock that the captured read data and the write data are the same, the PHY 150 may perform the operation of applying each of the plurality of delay codes WCK delay code 3 to WCK delay code 15 to generate a plurality of second write clocks WCK″_pr_delay code 3 to WCK″_pr_delay code 15, and capturing the read data based on the read strobe signal CRCK_select.

If all of the plurality of delay codes have been applied (S1061, YES), the training circuit 110 determines whether the plurality of write clocks WCK_p0 to WCKpm have all been transmitted to the memory device (S1063).

If the plurality of write clocks have not all been transmitted to the memory device (S1063, NO), the training circuit 110 determines the second write clock WCK_pr+1 among the plurality of write clocks as the first target write clock (S1064), and the process returns to operation S1054.

Referring to FIG. 10, the PHY 150 may be determined the first delay code WCK delay code 0 as the target delay code. The PHY 150 may generate the second target write clock WCK″_pr+1_delay code 0 by applying the first delay code WCK delay code 0. The PHY 150 may transmit the write data to the memory device 200 based on the second target write clock WCK″_pr+1_delay code 0. The PHY 150 may capture the read data based on the read strobe signal CRCK_select. The training circuit 110 determines whether the read data captured based on the read strobe signal CRCK_select and the write data are the same. Until there is the second target write clock that the captured read data and the write data are the same, the PHY 150 may perform the operation of applying each of the plurality of delay codes WCK delay code 1 to WCK delay code 15 to generate a plurality of second write clocks WCK″_pr+1_delay code 1 to WCK″_pr+1_delay code 15 and capturing the read data based on the read strobe signal CRCK_select.

If the plurality of write clocks have all been transferred to the memory device (S1063, YES), the training circuit 110 determines the delay code corresponding to the second target write clock with which the captured read data and the write data are most similar as the write delay code, and generates the reception timing information based on the write delay code (S1065).

In FIG. 10, for better understanding and ease of description, the plurality of write clocks (WCK_pr, WCK″_pr_delay code 0, WCK″_pr_delay code 1, . . . , WCK″_pr+1, WCK″_pr+1_delay code 0, WCK″_pr+1_delay code 1, Etc.) are shown as being generated at the same timing, but embodiments are not limited to this, and, in an embodiment, each write clock may be created at a different time. For example, in an embodiment, the first write clock WCK_pr+1 may be generated after the processor 100 transmits the second command set 1002 to the memory device 200.

Again referring to FIG. 6, the processor 100 performs command bus training on the memory device 200 (S107).

For example, the processor 100 and the memory device 200 may perform a command/address training operation so that the command CMD and the address ADD may be latched at a desired timing by the clock CK.

The semiconductor device 10 may determine the transmission timing of the command/address signal CA by performing the clock CK training on the command/address signal CA. In some embodiments, the semiconductor device 10 may determine the toggle timing of the clock CK and generate the toggle timing information.

Referring to FIG. 11 and FIG. 12 together, the PHY 150 receives the mode signal indicating the command training mode from the training circuit 110 (S1071).

The PHY 150 generates a third command set including at least one write command and at least one read command, and a plurality of clocks CK with different phases based on the mode signal APB_M.

In some embodiments, the training circuit 110 may pre-store the third command set corresponding to the command bus training operation. For example, as shown in FIG. 12, the plurality of third command sets 1201, and 1202 may each include an active command, a write command, read command, and a precharge command. In some embodiments, the PHY 150 may generate a plurality of clocks CK_p0 to CK_pn with different phases.

The training circuit 110 determines the first clock CK_pq among the plurality of clocks CK_p0 to CK_pn as the first target clock (S1073).

The PHY 150 may generate the first clock CK_pq based on the mode signal APB_M.

The training circuit 110 determines the first delay code among the plurality of delay codes as the target delay code (S1074).

In some embodiments, the training circuit 110 may pre-store a plurality of delay codes corresponding to the command bus training operation. The PHY 150 may obtain the information about the plurality of delay codes based on the mode signal APB_M.

In FIG. 12, the training circuit 110 may determine the first delay code CK delay code 0 as the target delay code.

The PHY 150 applies the target delay code CK delay code 0 to the first target clock CK_pq to generate the second target clock CK″_pq_delay code 0 (S1075).

The PHY 150 transmits the write data based on the write delay code (S1076).

Here, the PHY 150 may transmit the write command based on the second target clock CK″_pq_delay code 0.

In some embodiments, the write delay code may be a code determined through the write training (S105). In FIG. 12, the PHY 150 may transmit the write data based on the optimal write clock WCK_select to which the write delay code determined through the write training operation (S105) is applied.

The PHY 150 receives the read data from the memory device in response to the read command.

Here, the PHY 150 may transmit the read command based on the second target clock CK″_pq_delay code 0.

The PHY 150 captures the read data based on the read delay code (S1078).

In some embodiments, the read delay code may be a code determined through the read training (S103). In FIG. 12, the PHY 150 may capture the read data based on the optimal read strobe signal CRCK_select to which the read delay code determined through the read training (S103) is applied.

The PHY 150 may transmit the captured read data to the training circuit 110.

The training circuit 110 determines whether there is a second target clock that the captured read data and the write data are the same (S1079).

If there is the second target clock that the captured read data and the write data the same (S1079, YES), the training circuit 110 determines the delay code corresponding to the second target clock as the command delay code, and generates the toggle timing information based on the command delay code (S1080).

In some embodiments, the training circuit 110 may determine the first delay code as the command delay code. In some embodiments, the training circuit 110 may generate the toggle timing information based on the clock CK_pq and the first delay code corresponding to the second target clock CK″_pq. Thereafter, the processor 100 may transmit the command to the memory device 200 based on the toggle timing information.

If there is no second target clock where the captured read data and write data are the same (S1079, NO), the training circuit 110 determines whether all of the plurality of delay codes have been applied (S1081).

The training circuit 110 may determine whether each of the plurality of delay codes has been applied to the first clock CK_pq as the target delay code.

If all plurality of delay codes have not been applied (S1081, NO), the training circuit 110 determines the second delay code among the plurality of delay codes as the target delay code (S1082) and the process returns to operation S1075.

In other words, the training circuit 110 may generate the second clock CK″_pq by applying the unapplied delay code among the plurality of delay codes to the first clock CK_pq) as the target delay code.

As shown in FIG. 12, the PHY 150 may generate the second clock CK″_pq_delay code 2 by applying the second delay code CK delay code 2. The PHY 150 may transmit the write command and the read command to the memory device 200 based on the second clock CK″_pq_delay code 2. The PHY 150 may capture the read data based on the read strobe signal CRCK_select. The training circuit 110 determines whether the read data captured based on the read strobe signal CRCK_select and the write data are the same). Until there is the second target clock that the captured read data and the write data are the same, the PHY 150 may perform the operation of generating the plurality of second clocks CK″_pq_delay code 3 to CK″_pq_delay code 15 by applying each of the plurality of delay codes CK delay code 3 to CK delay code 15, and capturing the read data based on the read strobe signal CRCK_select.

If all of the plurality of delay codes have been applied (S1081, YES), it is determined whether all of the plurality of clocks have been transmitted to the memory device (S1083).

If the plurality of clocks have not all been transmitted to the memory device (S1083, NO), the second clock among the plurality of clocks is determined as the first target clock (S1084) and the process returns to operation S1074.

Referring to FIG. 12, the PHY 150 may determine the first delay code CK delay code 0 as the target delay code. The PHY 150 may generate a second target clock CK″_pr+1_delay code 0 by applying the first delay code CK delay code 0. The PHY 150 may transmit the write command and the read command to the memory device 200 based on the second target clock CK″_pr+1_delay code 0. The PHY 150 may capture the read data based on the read strobe signal CRCK_select. The training circuit 110 determines whether the read data captured based on the read strobe signal CRCK_select and the write data are the same. Until there is the second target clock that the captured read data and the write data are the same, the PHY 150 may perform of generating the plurality of second clock CK″_qr+1_delay code 1 to CK″_qr+1_delay code 15 by applying each of the plurality of delay codes CK delay code 1 to CK delay code 15, and capturing the read data based on the read strobe signal CRCK_select.

If the plurality of clocks have all been transferred to the memory device (S1083, YES), the delay code corresponding to the second target clock where the captured read data and the write data are most similar is determined as the command delay code, and the toggle timing information is generated based on the command delay code (S1085).

In FIG. 12, for better understanding and ease of description, although the plurality of clocks CK_pq, CK″_pq_delay code 0, CK″_pq_delay code 1, . . . , CK″_pq 1, CK″_pq 1_delay code 0, CK″_pq 1_delay code 1, etc.) are shown as being created at the same timing, embodiments are not limited to this and, in some embodiments, each clock may be created at a different time. For example, in an embodiment, the first clock CK_pq+1 may be generated after the processor 100 transmits the third command set 1202 to the memory device 200.

In FIG. 6, when the semiconductor device 10 operates in the training mode, it is shown that the read training operation, the write training operation, and the command bus training operation are performed sequentially, but embodiments are not limited to this, and, in some embodiments, the semiconductor device 10 may perform a plurality of training operations in an appropriate order. In some embodiments, the semiconductor device 10 may perform only one operation among the read training operation, the write training operation, or the command bus training operation. In some embodiments, the semiconductor device 10 may perform one or more operations among the read training operation, the write training operation, or the command bus training operation. For example, in an embodiment, when the semiconductor device 10 operates in the training mode, only the read training operation and the write training operation may be performed.

After the semiconductor device 10 operates in the training mode, the semiconductor device 10 may be operated in a normal operation. For example, the memory controller 130 may obtain a data by sampling the data signal DQ received from the memory device 200 based on the reception timing determined according to the read training operation. The memory controller 130 may transmit the data signal DQ to the memory device 200 based on the transmission timing determined according to the write training operation. In some embodiments, the memory controller 130 may transmit the read command or the write command to the memory device 200 based on the toggle timing determined according to the command bus training operation.

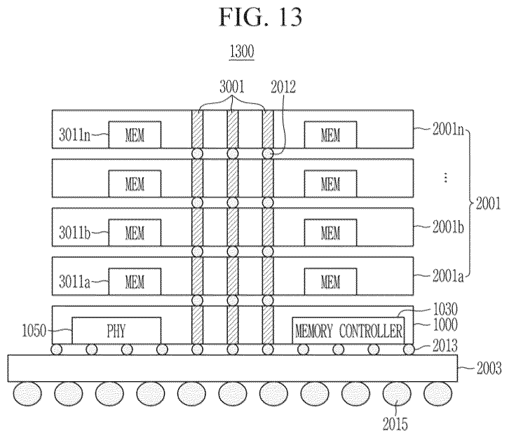

FIG. 13 is a view showing a semiconductor package according to an embodiment.

Referring to FIG. 13, the semiconductor package 1300 may include stacked core dies 2001, a system on chip 1000, and a semiconductor die 2003.

The stacked core die 2001 may include plurality of core dies 2001a to 2001n (n is an integer greater than 1). Each of the plurality of core dies 2001a to 2001n may include corresponding memories 3011a to 3011n. The plurality of core dies 2001a to 2001n may correspond to the plurality of core dies 201a to 201n of FIG. 1 and FIG. 5.

The plurality of core dies 2001a to 2001n each may include a memory cell array. The plurality of core dies 2001a to 2001n each may receive signals from the system on chip 1000 through a physical layer (PHY) 1050, or transmit signals to the system on chip 1000. The physical layer (PHY) 1050 may correspond to the PHY 150 described with reference to FIG. 2 to FIG. 4.

The plurality of core dies 2001a to 2001n may be electrically connected to each other through a plurality of TSVs 3001 and a plurality of bumps 2012. The plurality of core dies 2001a to 2001n may receive signals provided to each channel from the system on chip 1000 through the bumps 2012 allocated for each channel. For example, the plurality of bumps 2012 may be micro bumps.

The system on chip 1000 may run applications supported by the semiconductor package 1300 by using the stacked core die 2001. For example, the system on chip 1000 may include at least one processor among a central processing unit (CPU), an application processor (AP), a graphic processing unit (GPU), a neural processing unit (NPU), a tensor processing unit (TPU), a vision processing unit (VPU), an image signal processor (ISP), or a digital signal processor (DSP) to perform specialize operations.

The system on chip 1000 may include the physical layer (PHY) 1050 and a memory controller 1030. The physical layer (PHY) 1050 may include a physical layer 1050 of the stacked core die 2001 and input/output circuits for transmitting/receiving signals. The system on chip 1000 may transmit signals to the plurality of core dies 2001a to 2001n through the interface circuits of the physical layer (PHY) 1050 and the plurality of TSVs 3001.

The physical layer (PHY) 1050 may detect optimal conditions for transmitting/receiving signals to ensure the data reliability between the system on chip 1000 and the stacked core die 2001. In some embodiments, the physical layer 1050 may generate a plurality of commands for training the stacked core die 2001 under the control of the system on chip 1000. For example, the physical layer 1050 may generate a command set including a plurality of commands (e.g., an active command, a read command, a write command, a precharge command, etc.) in response to each training operation. In some embodiments, the physical layer 1050 may control the interval between the plurality of commands within the command set.

In some embodiments, the physical layer (PHY) 1050 may generate a plurality of clocks for training the stacked core die 2001 under the control of the system on chip 1000. For example, the physical layer 1050 may generate a plurality of read clocks with different phases to perform a training for the read operation between the system on chip 1000 and the stacked core die 2001. The physical layer 1050 may receive the read strobe signal generated from the target core die that is one of the plurality of core dies 2001a to 2001n based on the read clock, and apply the plurality of delays to the received read strobe signal to capture the read data received from the target core die. As the physical layer 1050 controls the phase of the read clock and the delay applied to the read strobe signal, the system on chip 1000 may detect the optimal condition when performing the read operation on the target core die.

For example, physical layer (PHY) 1050 may generate the plurality of write clocks with different phases to perform the training for the write operation between the system on chip 1000 and the stacked core die 2001. The physical layer 1050 may transmit the write data to the target core die based on the write clock. The physical layer 1050 may read the data from the target core die to determine whether the write data has been written accurately. As the physical layer 1050 controls the phase of the write clock and the delay applied to the write clock, the system on chip 1000 may detect the optimal condition when performing the write operation on the target core die.

For example, in some embodiments, the physical layer 1050 may generate a plurality of clocks with different phases to perform the training for the command transmitting/receiving operation between the system on chip 1000 and the stacked core die 2001. The physical layer 1050 may transmit the write data along with the write command to the target core die based on the clock. The physical layer 1050 may transmit the read command to the target core die based on the clock. As the physical layer 1050 determines whether the write data is properly written to the target core die by controlling the phase of the clock and the delay applied to the clock, the system on chip 1000 may detect the optimal conditions for transmitting/receiving the commands for the target core die.

In some embodiments, in the semiconductor package 1300, the stacked core die 2001 may be directly stacked on the system on chip 1000, so a skew between the clock and the data due to errors generated in the process transmitting the signal may be reduced between the system on chip 1000 and the stacked core die 2001

In some embodiments, the semiconductor package 1300 may perform the training on the signals that are directly transmitted/received between the system on chip 1000 and the stacked core die 2001, so the time required for the training may be reduced.

The memory controller 1030 may control the overall operation of the stacked core die 2001. The memory controller 1030 may transmit the signals for controlling the stacked core die 2001 to the stacked core die 2001 through the physical layer 1050. The memory controller 1030 may correspond to the memory controller 130 of FIG. 1.

A plurality of bumps 2013 may be attached to the upper part of the semiconductor die 2003, and a solder ball 2015 may be attached to the lower part. For example, in some embodiments, the plurality of bump 2013 may be flip-chip bumps. The semiconductor package 1300 may transmit/receive signals with other external packages or semiconductor devices through the solder ball 2015. For example, in some embodiments, the semiconductor die 2003 may be a printed circuit board (PCB).

The plurality of core dies 2001a to 2001n may include a TSV region. TSVs 3001 configured to pass through the dies 2001a-2001n may be placed in the TSV region. The system on chip 1000 is capable of transmitting/receiving various signals with the plurality of core dies 2001a to 2001n through the TSVs 3001. The plurality of core dies 2001a to 2001n may each transmit/receive signals with other core dies through the TSVs 3001. In this case, the signals may be independently transmitted/received through the corresponding TSVs 3001 for each channel. For example, when an external host device (e.g., the memory controller 100 in FIG. 1) transmits a data signal to a first channel to store data in the memory cell of the first channel, a buffer die may transmit the data signal to the first core die 2001a through the TSVs 3001 corresponding to the first channel. Accordingly, the data may be stored in the memory cell of the first channel.

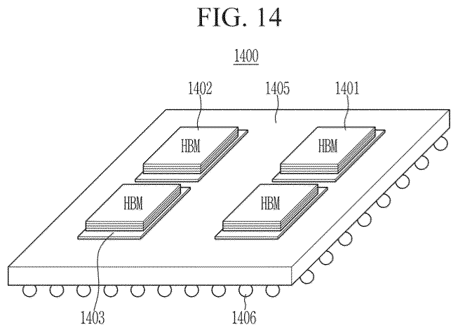

FIG. 14 is a perspective view showing an example of a semiconductor package according to an embodiment.

Referring to FIG. 14, the semiconductor package 1404 may include one or more stacked memory devices 1401, a central processing unit 1402, and a graphics processor 1403. The stacked memory device 1401, the central processing unit 1402, and the graphic processor 1403 may be mounted on the package substrate 1405. The central processing unit 1402 and the graphic processor 1403 may be implemented to perform the functions of the host device described above.

The stacked memory device 1401 may be implemented in various forms, and in some embodiments, the stacked memory device 1401 may be a stacked memory device in a form of a high bandwidth memory (HBM) in which multiple layers are stacked as described above. The stacked memory device 1401 may include the core dies 201a-201n or 2001a-2001n described with reference to FIG. 1 to FIG. 13.

In an embodiment, the central processing unit 1402 may include a physical layer PHY, and a communication may be performed between the stacked memory devices 1401 and the memory controller included in the central processing unit 1402 through the physical layer PHY.

In some embodiments, the central processing unit 1402 may include a training circuit. The physical layer PHY may generate a plurality of command sets for training the stacked memory device 1401 based on the control of the training circuit.

The physical layer PHY may detect optimal conditions for transmitting/receiving signals to ensure the data reliability between the central processing unit 1402 and the stacked memory device 1401. In some embodiments, the physical layer PHY may generate a plurality of commands for training the stacked memory device 1401. For example, the physical layer PHY may generate a command set including a plurality of commands (e.g., the active command, the read command, the write command, the precharge command, etc.) in response to each training operation. In some embodiments, the physical layer PHY may control the interval between the plurality of commands within the command set.

In some embodiments, the physical layer PHY may generate a plurality of clocks for training the stacked memory device 1401. For example, the physical layer PHY may generate a plurality of signals (e.g., the read clock, the write clock, the clock) with different phases. to perform the training on the read operation, the write operation, and the command transmitting/receiving operation through a command bus between the central processing unit 1402 and the stacked memory device 1401.

In some embodiments, in the semiconductor package 1404, the stacked memory device 1401 may be stacked on the central processing unit 1402, so the skew between the clock and the data due to errors occurring in the process of transmitting the signals between the central processing unit 1402 and the stacked memory device 1401 may be reduced. In some embodiments, the semiconductor package 1404 may perform the training on the signals transmitted/received between the central processing unit 1402 and the stacked memory device 1401, so the time required for the training may be reduced.

In FIG. 14, a configuration for the training during the signal transmitting/receiving between the central processing unit 1402 and the stacked memory device 1401 is described, but embodiments are not limited to this, and, in some embodiments, the content described using the central processing unit 1402 as an example may also be applied to the configuration for the training during the signal transmitting/receiving between the graphic processor 1403 and the stacked memory device 1401.

While various embodiments have been described in connection with the drawings, it is to be understood that the various embodiments are not limiting, but, on the contrary, are intended to cover various modifications and equivalent arrangements, each of which are included within the spirit and scope of the appended claims.

What is claimed is:

1. A semiconductor device comprising:
at least one core die;
a plurality of through silicon vias (TSV) configured to penetrate the at least one core die; and
a processor connected to the at least one core die through a TSV of the plurality of TSVs,
wherein the processor is configured to generate a first command set including a plurality of commands and a plurality of clock signals having different phases for a target core die among the at least one core die, and to perform a training operation for the target core die based on the first command set and the plurality of clock signals.

2. The semiconductor device of claim 1, wherein the processor includes:
a training circuit configured to generate a mode signal for the first command set and the plurality of clock signals, and determine a reception timing of data received from the target core die and a transmission timing of data transmitted to the target core die based on results of the training operation, and
a physical layer (PHY), including a command control slice configured to generate the first command set and a data control slice configured to generate the plurality of clock signals, based on the mode signal.

3. The semiconductor device of claim 2, wherein:
the mode signal includes information about the plurality of commands included in the first command set and time intervals between respective ones of the plurality of commands,
the command control slice includes a command first in first out (FIFO) circuit configured to generate command generation data based on the mode signal, and a command generator configured to sequentially generate the plurality of commands included in the first command set based on the command generation data.

4. The semiconductor device of claim 2, wherein:
the mode signal is a first mode signal that indicates a read training operation, and the first command set includes at least one read command,
the data control slice includes:
a read clock generator configured to generate a plurality of read clocks having different phases based on the first mode signal;
a second delay circuit configured to generate a second read clock by applying a delay to a first read clock that has a first phase among the plurality of read clocks; and
a second TSV input/output circuit connected to the plurality of TSVs, the second TSV input/output circuit configured to receive a first read strobe signal and a read data corresponding to the at least one read command from the target core die, based on the second read clock.

5. The semiconductor device of claim 4, wherein:
the second delay circuit is configured to receive the first read strobe signal from the second TSV input/output circuit and apply the delay to the first read strobe signal to generate a second read strobe signal,
the data control slice further includes a data receiver configured to generate captured read data by sampling the read data based on the second read strobe signal, and the training circuit is configured to determine the reception timing based on the captured read data.

6. The semiconductor device of claim 2, wherein:
the mode signal is a second mode signal that indicates a write training operation, and the first command set includes at least one write command and at least one read command,
the data control slice includes:
a write clock generator configured to generate a plurality of write clocks having different phases based on the second mode signal,
a second delay circuit configured to generate a second write clock by applying a delay to a first write clock having a first phase among the plurality of write clocks, and a second TSV input/output circuit connected to the plurality of TSVs, the second TSV input/output circuit configured to transmit write data to the target core die based on the second write clock, and receive read data corresponding to the at least one read command from the target core die based on the reception timing, and
the training circuit is configured to determine the transmission timing based on the write data and the read data.

7. The semiconductor device of claim 2, wherein:
the mode signal is a third mode signal that indicates a command bus training operation, and the first command set includes at least one write command and at least one read command,
the command control slice includes:
a clock generator configured to generate a plurality of clocks having different phases based on the third mode signal,
a first delay circuit configured to generate a second clock by applying a delay to a first clock having a first phase among the plurality of clocks, and
a first TSV input/output circuit connected to the plurality of TSVs, the first TSV input/output circuit configured to transmit the at least one write command and the at least one read command to the target core die based on the second clock, transmit write data to the target core die based on the transmission timing, and receive read data corresponding to the at least one read command from the target core die based on the reception timing, and
the training circuit is configured to determine a toggle timing for the plurality of clocks transmitted to the at least one core die based on the write data and the read data.

8. The semiconductor device of claim 2, wherein:
the processor further includes a memory controller configured to control the at least one core die, and
the physical layer further includes:
a DDR physical interface connected to the memory controller and configured to transmit/receive signals with the memory controller, and
an advanced peripheral bus (APB) interface connected to the training circuit and configured to transmit/receive signals with the training circuit.

9. A training method of a semiconductor device, the training method comprising:
writing a training pattern to a target core die of at least one core die by a processor connected to at least one core die through a plurality of through silicon vias;
performing a training operation for a target core die based on a first command set including a plurality of commands for the target core die and a mode signal for a plurality of clock signals having different phases; and
determining a reception timing of read data received from the target core die and a transmission timing of transmit data transmitted to the target core die based on a result of the training operation.

10. The training method of the semiconductor device of claim 9, wherein performing the training operation includes:
receiving a first mode signal indicating a read training operation for the target core die,
generating the first command set including at least one read command and a plurality of read clocks having different phases based on the first mode signal,
determining a first read clock with a first phase among the plurality of read clocks as a target read clock,
transmitting the first command set and the target read clock to the target core die,
receiving read data that corresponds to a first read strobe signal and the at least one read command from the target core die based on the target read clock,
determining a first delay code among a plurality of delay codes as a target delay code,
generating a second read strobe signal by applying a delay corresponding to the target delay code to the first read strobe signal,
sampling the read data based on the second read strobe signal,
comparing the read data that is sampled with the training pattern, and
determining the reception timing based on a result of the comparing.

11. The training method of the semiconductor device of claim 10, wherein the comparing includes:
when the read data that is sampled and the training pattern are different, determining whether all of the plurality of delay codes have been applied to the first read strobe signal,
when all of the plurality of delay codes have not been applied, determining a second delay code among the plurality of delay codes as the target delay code; and
when all of the plurality of delay codes have been applied, determining a second read clock having a second phase among the plurality of read clocks as the target read clock.

12. The training method of the semiconductor device of claim 9, wherein performing the training operation includes:
receiving a second mode signal indicating a write training operation for the target core die;
generating a second command set including at least one write command and at least one read command and a plurality of write clocks having different phases based on the second mode signal;
determining a first write clock with a first phase among the plurality of write clocks as a first target write clock;
determining a first delay code among a plurality of delay codes as a target delay code;
generating a second target write clock by applying a delay corresponding to the target delay code to the first target write clock;
transmitting write data to the target core die based on the second target write clock;
receiving read data corresponding to the at least one read command;
sampling the read data based on the reception timing;
comparing the read data that is sampled with the write data; and
determining the transmission timing based on a result of the comparing.

13. The training method of the semiconductor device of claim 12, wherein the comparing includes:
when the read data that is sampled and the write data are different, determining whether all of the plurality of delay codes have been applied to the first target write clock;
when all of the plurality of delay codes have not been applied, determining a second delay code among the plurality of delay codes as the target delay code; and
when all the plurality of delay codes have been applied, determining a second write clock with a second phase among the plurality of write clocks as the first target write clock.

14. The training method of the semiconductor device of claim 9, wherein performing the training operation includes:
receiving a third mode signal indicating a command training operation for the target core die;
generating a third command set including at least one write command and at least one read command and a plurality of clocks having different phases based on the third mode signal;
determining a first clock with a first phase among the plurality of clocks as a first target clock;
determining a first delay code among a plurality of delay codes as a target delay code;
generating a second target clock by applying a delay corresponding to the target delay code for the first target clock;
transmitting at least one write command to the target core die based on the second target clock and transmitting write data to the target core die based on the transmission timing;
transmitting at least one read command to the target core die based on the second target clock;
receiving read data corresponding to the at least one read command;
sampling the read data based on the reception timing;
comparing the read data that is sampled with the write data; and
determining a toggle timing for the plurality of clocks based on a result of the comparing.

15. The training method of the semiconductor device of claim 14, wherein the comparing includes:
when the read data that is sampled and the write data are different, determining whether all of the plurality of delay codes have been applied to the first target clock;
when all of the plurality of delay codes have not been applied, determining a second delay code among the plurality of delay codes as the target delay code; and
when all the plurality of delay codes have been applied, determining a second clock with a second phase among the plurality of clocks as the first target clock.

16. A semiconductor device comprising:
at least one core die; and
a processor connected to the at least one core die through a plurality of through silicon vias (TSV) that penetrate the at least one core die,
wherein the processor includes:
a training circuit configured to, when the processor operates in a training mode, perform a training operation for a target core die among the at least one core die by generating a mode signal for a first command set including a plurality of commands for the target core die and for a plurality of clock signals having different phases, and
a physical layer configured to generate the first command set and the plurality of clock signals based on the mode signal.

17. The semiconductor device of claim 16, wherein:
the mode signal includes information about the plurality of commands included in the first command set and time intervals between respective ones of the plurality of commands,
when the mode signal is a first mode signal that indicates a read training operation, the first command set includes at least one read command,
the physical layer is configured to generate a plurality of read clocks having different phases based on the first mode signal, generate a second read clock by applying a first delay to a first read clock having a first phase among the plurality of read clocks, transmit the second read clock to the target core die, receive a first read strobe signal from the target core die, generate a second read strobe signal by applying a second delay to the first read strobe signal, receive read data in response to the at least one read command from the target core die, and sample the read data based on the second read strobe signal, and
the training circuit is configured to determine a reception timing of data received from the target core die based on the read data that is sampled.

18. The semiconductor device of claim 16, wherein:
when the mode signal is a second mode signal indicating a write training operation, the first command set includes at least one write command and at least one read command,
the physical layer is configured to generate a plurality of write clocks having different phases based on the second mode signal, generate a second write clock by applying a first delay to a first write clock with a first phase among the plurality of write clocks, transmit a write data to the target core die based on the second write clock, and receive read data in response to the at least one read command from the target core die, and
the training circuit is configured to determine a transmission timing of data transmitted to the target core die based on the write data and the read data.

19. The semiconductor device of claim 16, wherein:
the training circuit is configured to determine a transmission timing of data transmitted to the target core die based on a result of the training operation,
when the mode signal is a third mode signal indicating a command bus training operation, the first command set includes at least one write command and at least one read command,
the physical layer is configured to generate a plurality of clocks having different phases based on the third mode signal, generate a second clock by applying a first delay to a first clock with a first phase among the plurality of clocks, transmit the at least one write command and the at least one read command to the target core die based on the second clock, transmit write data to the target core die based on the transmission timing, and receive read data in response to the at least one read command from the target core die, and
the training circuit is configured to determine a toggle timing for the plurality of clocks transmitted to the target core die based on the write data and the read data.

20. The semiconductor device of claim 16, wherein:
the processor further includes a memory controller configured to control the at least one core die when the processor operates in a normal mode; and
the physical layer further includes:
a DDR physical interface (DFI) interface connected to the memory controller and configured to transmit/receive signals with the memory controller, and
an advanced peripheral bus (APB) interface connected to the training circuit and configured to transmit/receive signals with the training circuit.
